(19) United States
(12) Patent Application Publication
(10) Pub. No.: US 2026/0016545 A1
(43) Pub. Date: Jan. 15, 2026

(54) BATTERY MONITORING SYSTEM

(71) Applicant: DENSO CORPORATION, Kariya-city (JP)

(72) Inventor: Yukihiro TOMONAGA, Kariya-city (JP)

(21) Appl. No.: 19/338,587

(22) Filed: Sep. 24, 2025

Related U.S. Application Data
(63) Continuation of application No. PCT/JP2024/009581, filed on Mar. 12, 2024.

(30) Foreign Application Priority Data
Mar. 28, 2023 (JP) 2023-051656

(51) Int. Cl. G01R 31/396; G01R 31/3835; H01M 10/42

(52) U.S. Cl. CPC G01R 31/396; G01R 31/3835; H01M 10/425; H01M 2010/4278

(57) ABSTRACT

A battery monitoring system of a battery having multiple battery cells, includes: multiple monitoring circuits each of which is connected in series via a communication path and uses a power of a battery module to acquire data relating to the battery module; a microcomputer that monitors the battery during a normal operation; and a communication bridge that is connected to the monitoring circuits via the communication path and transitions to a low power consumption mode when the microcomputer is in a sleep mode. The communication bridge includes: an instruction unit that activates from the low power consumption mode autonomously from the microcomputer using a power source different from the battery module and issues an instruction to acquire the data; an acquisition unit that acquires the data from the monitoring circuits; and a determination unit that determines whether the battery is in an anomaly state.

### CROSS REFERENCE TO RELATED APPLICATION

The present application is a continuation application of International Patent Application No. PCT/JP2024/009581 filed on March 12, 2024, which designated the U.S. and claims the benefit of priority from Japanese Patent Application No. 2023- 051656 filed on March 28, 2023. The entire disclosures of all of the above applications are incorporated herein by reference.

### TECHNICAL FIELD

The present disclosure relates to a battery monitoring system.

### BACKGROUND

For example, a vehicle such as an electric vehicle (i.e., EV) has an assembled battery for running the vehicle such as a lithium ion battery. An assembled battery has a configuration in which battery modules are combined, and generally, a monitor equipped with a monitoring circuit monitors the state of each battery module and determines whether there is an anomaly in the battery state.

### SUMMARY

According to an example, a battery monitoring system of a battery having multiple battery cells, may include: multiple monitoring circuits each of which is connected in series via a communication path and uses a power of a battery module to acquire data relating to the battery module; a microcomputer that monitors the battery during a normal operation; and a communication bridge that is connected to the monitoring circuits via the communication path and transitions to a low power consumption mode when the microcomputer is in a sleep mode. The communication bridge may include: an instruction unit that activates from the low power consumption mode autonomously from the microcomputer using a power source different from the battery module and issues an instruction to acquire the data; an acquisition unit that acquires the data from the monitoring circuits; and a determination unit that determines whether the battery is in an anomaly state.

### BRIEF DESCRIPTION OF THE DRAWINGS

The above and other features of the present disclosure will become more apparent from the following detailed description made with reference to the accompanying drawings. In the drawings:

FIG. 1 is an electrical configuration diagram schematically showing a battery monitoring system according to a first embodiment; and

FIG. 2 is an electrical configuration diagram schematically showing the internal configuration of the communication bridge and the monitoring circuit of the first embodiment;

FIG. 3 is a flowchart illustrating an operation according to the first embodiment;

FIG. 4 is an explanatory diagram of a signal transmission and reception sequence under a normal condition in the first embodiment;

FIG. 5 is an explanatory diagram of a signal transmission and reception sequence under an anomaly condition in the first embodiment;

FIG. 6 is a first diagram illustrating the anomaly notification method according to the first embodiment;

FIG. 7 is a second diagram illustrating the anomaly notification method according to the first embodiment;

FIG. 8 is a first diagram illustrating the method for reading data of a battery according to the first embodiment;

FIG. 9 is a second diagram illustrating the method for reading data of a battery according to the first embodiment;

FIG. 10 is an electrical configuration diagram schematically showing the internal configuration of the communication bridge and the monitoring circuit according to a comparison example;

FIG. 11 is a first diagram showing a configuration example of a communication connection mode according to a second embodiment; and

FIG. 12 is a second diagram showing a configuration example of a communication connection mode according to a second embodiment.

### DETAILED DESCRIPTION

According to conventional technique, when the circuit configuration of a battery monitoring system is operating in a low power consumption mode, and the microcomputer is in a sleep mode, the monitoring circuit disposed at the top of the monitoring circuits insulated in a ring shape to the microcomputer functions as the master. The master monitoring circuit then wakes up only one slave monitoring circuit. The woken up monitoring circuit then monitors whether or not there is an anomaly in the battery module, and transmits the result to the next slave monitoring circuit. The multiple monitoring circuits sequentially repeat such wake-up and monitoring sequences to determine whether or not there is an anomaly in each battery module.

In this technique, when the circuit configuration of the battery monitoring system is operating in a low power consumption mode, an arbitrary monitoring circuit is designated as the master, and the other monitoring ICs provide slaves. Since the master needs to wake up when the specific time is reached, so that it is necessary to count up during the sleep mode. This increases current consumption by the amount of the count-up operation.

On the other hand, on the slave side, there is no need to count up, so the operations of the master and slave are different from each other, and a difference in current consumption is generated for each monitored battery stack. This feature may tend to increase the power consumption of the master monitoring circuit. Although it is required that the power consumption of the battery modules be equalized, it is not possible to equalize the power consumption of the battery modules.

An object of the present embodiments is to provide a battery monitoring system that is capable of monitoring for the presence or absence of anomaly while equalizing the power consumption of battery modules as much as possible.

A battery monitoring system according to one aspect of the present embodiments includes a plurality of monitoring circuits, a microcomputer, and a communication bridge. The plurality of monitoring circuits are connected in series via communication paths and each monitor circuit uses the power of the battery module to which the monitoring circuit is assigned to acquire data relating to that battery module. Under the normal operation, the microcomputer instructs multiple monitoring circuits to monitor the battery and monitors the battery state. The communication bridge is a circuit that is connected to at least one of the multiple monitoring circuits via a communication path and instructs the acquisition of data. When the microcomputer is in a sleep mode, the communication bridge transfers to a low power consumption mode that consumes less power than the normal operation.

The communication bridge uses a power source different from the battery module and activates from a low power consumption mode autonomously from the microcomputer, instructs the monitoring circuit to acquire the data related to the battery, and acquires the data from multiple monitoring circuits via the communication. The communication bridge then determines whether the battery state is anomaly or not based on the acquired data.

Therefore, although the monitoring circuit activates from the low power consumption mode and acquires the data, the monitoring circuit does not determine whether or not there is an anomaly in the battery, but only detects the anomaly. When the communication bridge activates from the low power consumption mode, the communication bridge acquires the data from a plurality of monitoring circuits via the communication and determines whether the battery state is anomaly.

Since the communication bridge determines whether or not there is an anomaly based on the data acquired from a plurality of monitoring circuits, the anomaly can be determined without activating the microcomputer. The activation time of each monitoring circuit that consumes the power from the battery module can be averaged, and the variation in current consumption of the battery modules can be minimized.

Embodiments are described below with reference to the drawings. In the following embodiments, substantially same or similar structural configurations are designated with the same or similar reference symbols to simplify the description.

### (First Embodiment)

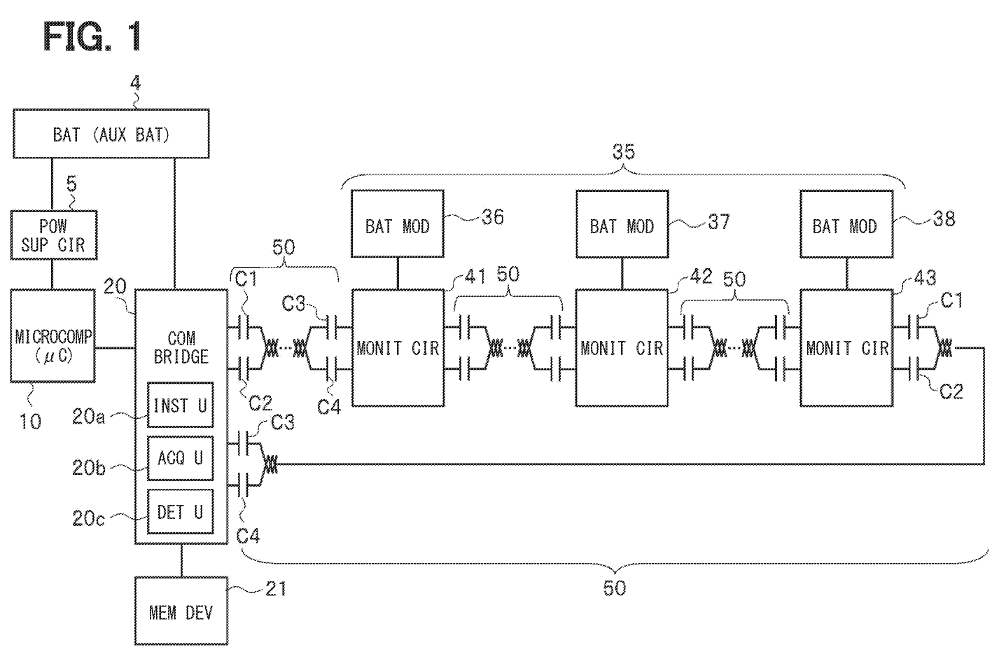

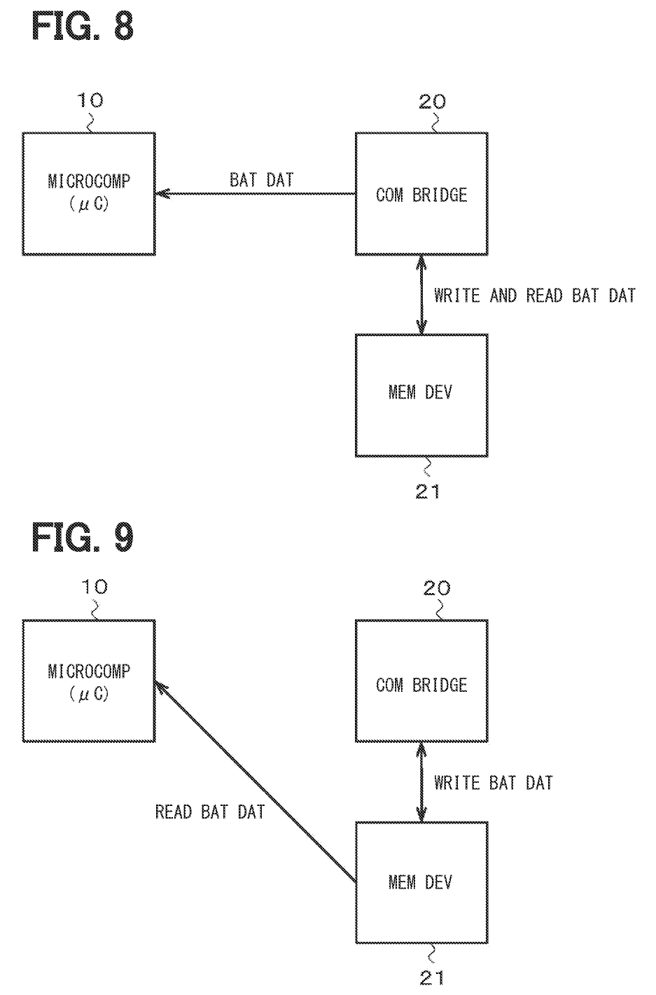

A first embodiment will be described with reference to FIGS. 1 to 10. The battery monitoring system 1 includes a microcomputer 10, a communication bridge 20, a memory device 21, a battery 35, a plurality of monitoring circuits 41 to 43, and an insulation communication path 50. The battery 35 is also called a battery pack. In the battery 35, multiple battery modules 36 to 38 are connected in series. The battery modules 36 to 38 may be connected in series parallel. The battery modules 36 to 38 are also referred to as a battery stack.

The battery modules 36 to 38 are assigned in advance to the monitoring circuits 41 to 43, respectively, and the monitoring circuits 41 to 43 operate using the power of the battery modules 36 to 38, respectively. The monitoring circuits 41 to 43 acquire the data related to the battery modules 36 to 38 that are assigned to the monitoring circuits 41 to 43, respectively.

The insulation communication paths 50 are provided between the communication bridge 20 and the monitoring circuit 41, between the monitoring circuit 41 and the monitoring circuit 42, and between the monitoring circuit 42 and the monitoring circuit 43, respectively. For example, the communication bridge 20 and the monitoring circuits 41 to 43 are connected in a daisy chain. This allows communication between the communication bridge 20 and the multiple monitoring circuits 41 to 43 in an insulation manner.

The insulation communication paths 50 are configured to be an insulation path using capacitors C1 to C4 as insulation elements. Although the insulation elements are shown as being constituted by the capacitors C1 to C4, transformers may be used in place of the capacitors C1 to C4. The communication bridge 20 is a circuit that converts the communication method between the microcomputer 10 and the multiple monitoring circuits 41 to 43. When the communication bridge 20 receives a data acquisition instruction from the microcomputer 10, the communication bridge 20 instructs the multiple monitoring circuits 41 to 43 to acquire the data.

The multiple monitoring circuits 41 to 43 are connected in parallel with each other. The monitoring circuits 41 to 43 are connected so as to be able to detect the voltages of the battery cells that constitutes each of the battery modules 36 to 38. The monitoring circuits 41 to 43 are assigned to the battery modules 36 to 38 as a monitoring target, respectively.

Each of the plurality of monitoring circuits 41 to 43 mainly includes of a battery monitoring IC. Here, the monitoring circuits 41 to 43 are shown as a feature that is provided by an IC, alternatively, the monitoring circuits 41 ot 43 may not be limited to this feature. Since the monitoring circuits 41 to 43 have the same configuration, the functional configuration of the monitoring circuit 41 will be described.

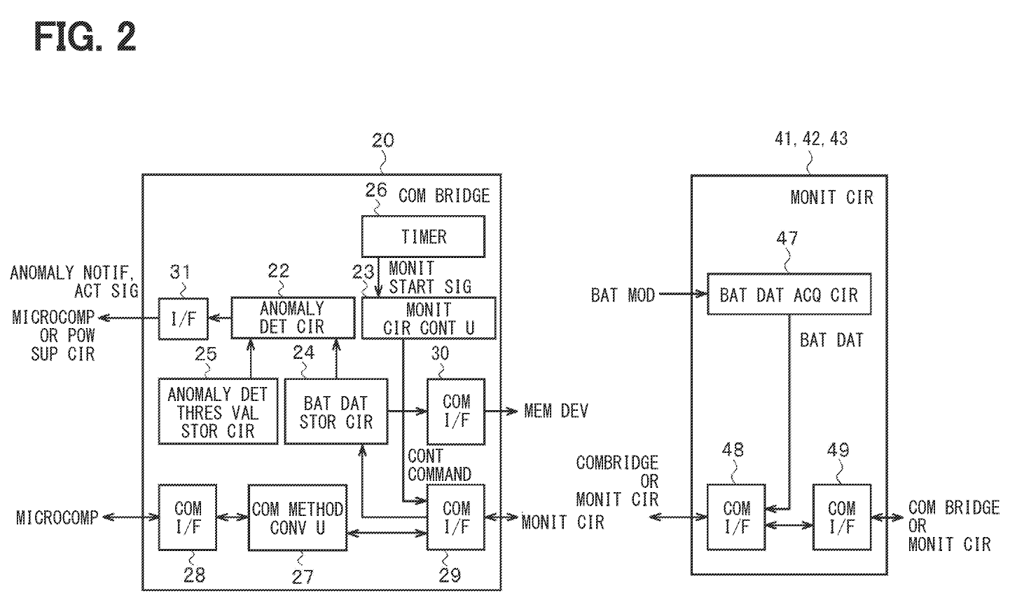

As illustrated in FIG. 2 ,the monitoring circuit 41 includes a battery data acquisition circuit 47 and communication I/Fs 48 and 49. The battery data acquisition circuit 47 acquires the data (hereinafter referred to as battery data) relating to the battery module 36 that is assigned to the battery data acquisition circuit 47 in advance among the battery modules 36 to 38. The battery data indicates voltage data of each battery cell that constitutes the corresponding battery module 36-38, position information of each battery cell, identification information (i.e., ID information) of the monitoring circuits 41-43, information for determining the time of acquisition, detection data of gas released from the battery 35, and the like. The communication I/Fs 48 and 49 of the monitoring circuit 41 are interfaces for communicating with the other monitoring circuits 42 and 43 and the communication bridge 20, and each of the communication I/Fs 48 and 49 include a built-in communication buffer.

The monitoring circuits 41 to 43 have the function of detecting the voltage of each battery cell of the battery modules 36 to 38, as well as an equalization function for equalizing the voltage of each battery cell of the battery modules 36 to 38, and a function for detecting the temperature of the battery modules 36 to 38. Each of the monitoring circuits 41 to 43 may include at least one of these functions.

### <Functions of microcomputer 10>

The microcomputer 10 operates by receiving power supply from a battery 4 (corresponding to a "power source", i.e., an auxiliary battery) different from the battery 35 through a power supply circuit 5. During the normal operation, the microcomputer 10 issues instructions to the multiple monitoring circuits 41 to 43 via the communication bridge 20 to acquire the data relating to the battery 35. During the normal operation, the microcomputer 10 acquires the data relating to the battery 35 from the multiple monitoring circuits 41 to 43, detects the current flowing through the battery 35, and estimates the SOC and SOH of the battery cells of the battery 35 based on the cell voltage and the cell current.

The SOH is an abbreviation of States Of Health, and is an index indicating a deterioration state of a battery 35. Note that the SOC is an index representing the state of charge of the battery 35, and is an abbreviation for State Of Charge. The microcomputer 10 can detect an anomaly of the battery cell by comparing the open circuit voltages of the battery cells in the battery 35 with each other and determining whether a difference between the open circuit voltages is disposed within a certain range.

For example, when a upper stage ECU (not shown) detects that an ignition switch has been turned off, the microcomputer 10 is transitioned to a sleep mode. When the microcomputer 10 is transitioned to the sleep mode, the operation of the power supply circuit 5 that supplies the power to the microcomputer 10 may be shut down, or the microcomputer 10 may be instructed to transition into the sleep mode. This makes it possible to suppress the power consumption of the microcomputer 10 and achieve low power consumption.

### <Functional Description of Communication Bridge 20>

The communication bridge 20 is connected in series and in cascade to a plurality of monitoring circuits 41 to 43. The communication bridge 20 operates by receiving the power from a battery 4 that is different from the battery 35. The communication bridge 20 is configured with a communication IC, and is connected to a memory device 21. Here, the communication bridge 20 is shown as a feature that is provided by an IC, alternatively, the communication bridge 20 may not be limited to this feature. As illustrated in FIG. 2, the communication bridge 20 includes an anomaly determination circuit 22 as a determination unit 20c, a monitoring circuit control unit 23, a battery data storage circuit 24, an anomaly determination threshold storage circuit 25, a timer 26, a communication method conversion unit 27, communication I/Fs 28 and 29, and an I/F 31.

The communication I/F 29 represents a communication interface with the connected monitoring circuit 41, and executes data communication with the monitoring circuit 41 according to an insulation communication method. The communication I/F 28 represents a communication interface with the connected microcomputer 10, and executes data communication with the microcomputer 10 according to a predetermined communication method.

The communication method conversion unit 27 represents a block that converts the communication method between the communication I/F 28 and the communication I/F 29. The communication method conversion unit 27 converts the communication method with the microcomputer 10 into a communication method suitable for insulation communication with the monitoring circuit 41. Conversely, the communication method conversion unit 27 converts the communication method suitable for the insulation communication with the monitoring circuit 41 into a communication method suitable for communication with the microcomputer 10.

The timer 26 counts time when the communication bridge 20 transitions to the low power consumption mode, and outputs a monitor start signal to the monitoring circuit control unit 23 after a predetermined time has elapsed. When the monitoring circuit control unit 23 receives a monitor start signal from the timer 26, the monitoring circuit control unit 23 outputs an activation signal to the monitoring circuits 41 to 43 via the communication I/F 29, and outputs an instruction signal for instructing to acquire the data.

The battery data storage circuit 24 is configured by a so-called buffer memory, and stores the battery data relating to the battery 35 acquired from the monitoring circuits 41 to 43 via the communication I/F 29. The battery data here may include voltage data and position information of each battery cell constituting the battery modules 36 to 38, and identification information (i.e., ID information) of the monitoring circuits 41 to 43 from which the data is acquired as a target. The battery data may include temperature data of the battery modules 36 to 38, the time of acquisition of the temperature data, detection data of gas released from the battery 35, and the like. The battery data storage circuit 24 writes the battery data in a non-volatile manner to the memory device 21 via the communication I/F 30.

The memory device 21 includes a non-volatile memory IC such as an EEPROM. Although the memory device 21 is shown as being configured from an EEPROM, the memory device 21 may not be limited to this feature and any type of memory may be used as long as it is equipped with a non-volatile memory.

The anomaly determination threshold storage circuit 25 stores a threshold value for anomaly determination, and stores, for example, a battery cell voltage threshold value and a temperature threshold value for the battery modules 36 to 38. The anomaly determination circuit 22 compares the data stored in the battery data storage circuit 24 with the anomaly determination threshold stored in the anomaly determination threshold storage circuit 25 to determine whether or not an anomaly exists. For example, the presence or absence of an anomaly is determined by comparing the voltage of each battery cell of the battery modules 36 to 38 with a threshold value and determining whether the voltage is disposed within a certain predetermined range.

When the anomaly determination circuit 22 determines that an anomaly has occurred, the anomaly determination circuit 22 is capable of notifying the microcomputer 10 or the power supply circuit 5 of the anomaly via the I/F 31. The data that the communication bridge 20 transmits to the microcomputer 10 is time-series data based on the battery data stored in the memory device 21, and the like. Specifically, examples of such data include temperature data of the battery modules 36 to 38, data on temperature changes over time based on voltage data of each battery cell, data on voltage changes of the battery cells, and time series data on detection data of gas released from battery 35.

The communication bridge 20 is configured as blocks as shown in FIG. 2 above, and the communication bridge 20 functionally can be said to have the functions of an instruction unit 20a, an acquisition unit 20b, and a determination unit 20c, as shown in FIG. 1. The instruction unit 20a has a function of activating from the low power consumption mode autonomously separately from the microcomputer 10 and instructing the monitoring circuits 41 to 43 to acquire data related to the battery 35. The acquisition unit 20b has a function of acquiring data from the monitoring circuits 41 to 43 through communication. The determination unit 20c has a function of determining whether the state of the battery 35 is in the anomaly state or not based on the acquired data.

The operation of the above-mentioned configuration will be mainly described while the microcomputer 10 is in the sleep mode. As described above, during the normal operation, when the microcomputer 10 acquires the state of the battery 35, the microcomputer 10 can monitor the state of the battery 35 in detail. When the microcomputer 10 becomes in the sleep mode to reduce power consumption, the communication bridge 20 and the multiple monitoring circuits 41 to 43 are also transitioned to a low power consumption mode in which power consumption is lower than normal. If the communication bridge 20 and the multiple monitoring circuits 41 to 43 are also transitioned to a low power consumption mode, the overall power consumption of the battery monitoring system 1 can be suppressed and reduced.

### <Monitoring operation during normal operation while the microcomputer 10 is in sleep mode>

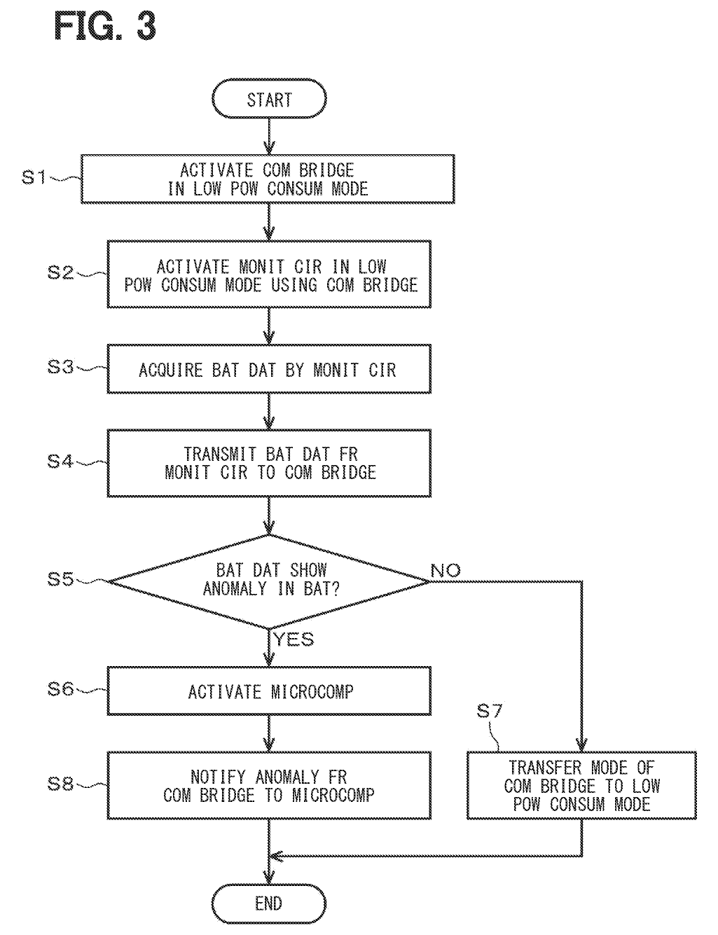

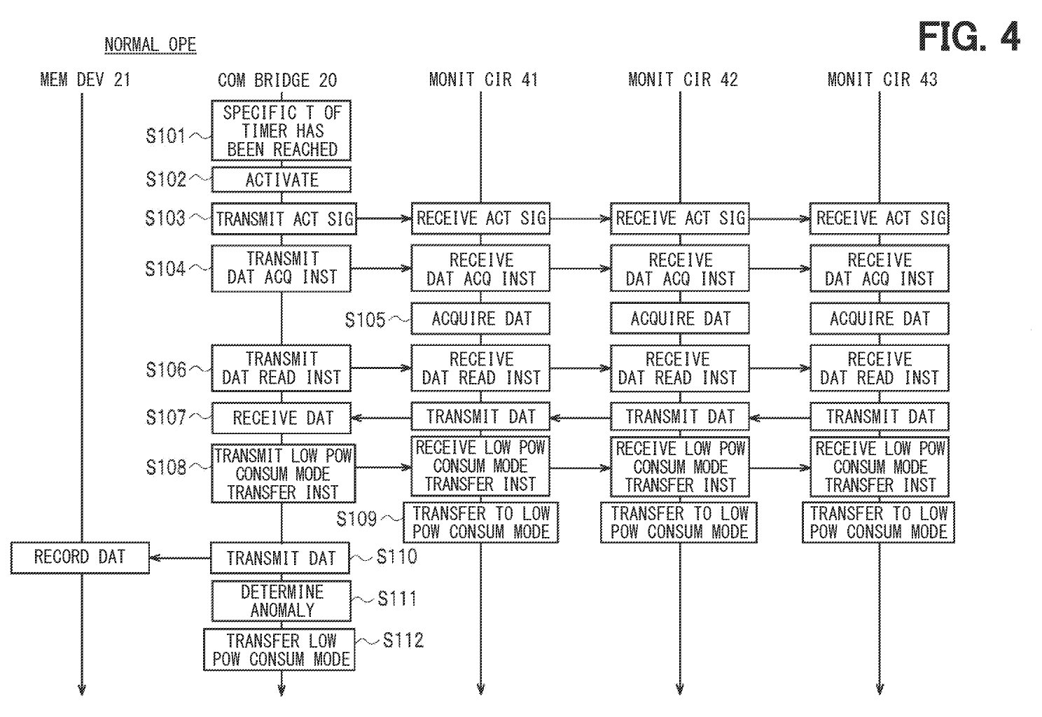

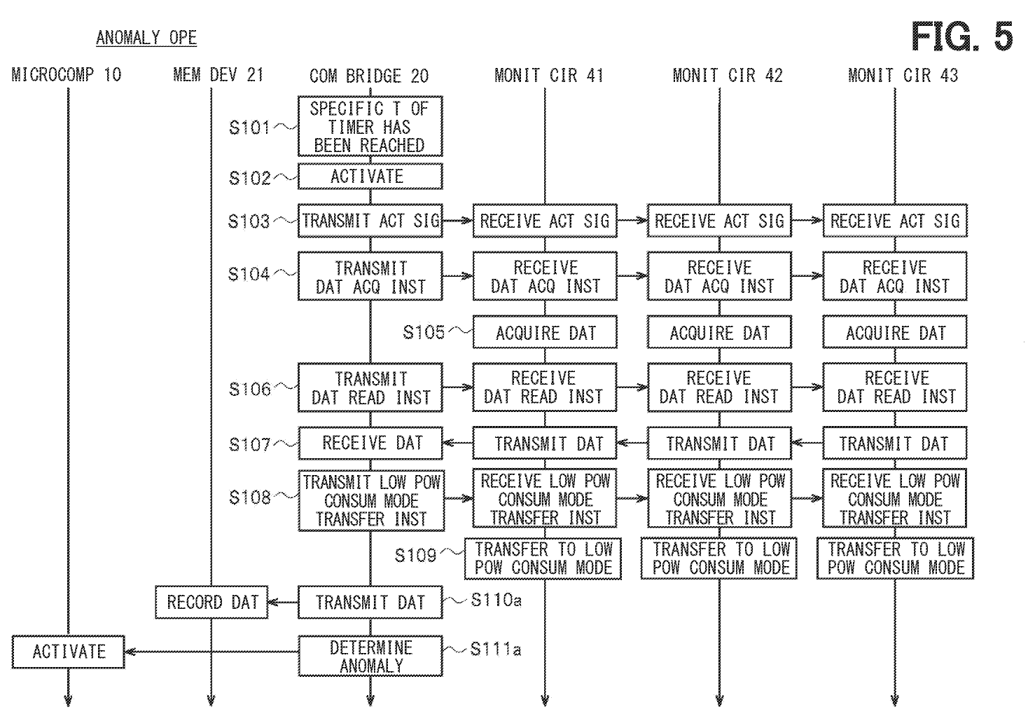

The operation of the monitoring circuits 41 to 43 in the normal operation (in FIG. 4) and in the anomaly operation (in FIG. 5) will be described together with the processing contents of the monitoring circuits 41 to 43 shown in FIG. 3. As shown in S101 of FIG. 4, in the low power consumption mode, the communication bridge 20 executes counting by the timer 26 and autonomously activates when a predetermined time has elapsed (at S1 of FIG. 3, and at S102 of FIG. 4 and FIG. 5).

The communication bridge 20 transmits a an activation signal to the plurality of monitoring circuits 41 to 43 through the insulation communication path 50 to activate each of the monitoring circuits 41 to 43 from the low power consumption mode (at S2 in FIG. 3, and at S103 in FIGS. 4 and 5).

The communication bridge 20 transmits data acquisition commands to the multiple monitoring circuits 41 - 43 via the insulation communication path 50. Each of the plurality of monitoring circuits 41 to 43 receives the data acquisition command (at S104 in FIG. 4 and FIG. 5). The plurality of monitoring circuits 41 to 43 acquire battery data in response to the data acquisition command (at S3 in FIG. 3, and at S105 in FIGS. 4 and 5).

Next, the communication bridge 20 transmits a data read command. Each of the plurality of monitoring circuits 41 to 43 receives the data read command (at S106 in FIG. 4 and FIG. 5). The plurality of monitoring circuits 41 to 43 transmit, to the communication bridge 20, the battery data acquired in response to the data read command (at S4 in FIG. 3, and at S107 in FIGS. 4 and 5). A specific example of a method for transmitting battery data will be described later in the second embodiment. The communication bridge 20 receives and acquires the battery data from the multiple monitoring circuits 41 to 43 (at S4 in FIG. 3). The communication bridge 20 stores the battery data in the battery data storage circuit 24.

Next, the communication bridge 20 transmits a command to transition to the low power consumption mode to the multiple monitoring circuits 41 to 43. Each of the plurality of monitoring circuits 41 to 43 receives the transition command to the low power consumption mode (at S108 in FIG. 4 and FIG. 5). Then, the plurality of monitoring circuits 41 to 43 transition to the low power consumption mode (at S109 in FIG. 4 and FIG. 5).

The communication bridge 20 transmits the battery data to the memory device 21 to be stored therein (at S110 in FIG. 4, and at S110a in FIG. 5). The communication bridge 20 determines whether the battery data indicates an anomaly in the battery 35 (at S5 in FIG. 3, S111 in FIG. 4, and S111a in FIG. 5). Specifically, the anomaly determination circuit 22 of the communication bridge 20 compares the battery data stored in the battery data storage circuit 24 with the threshold value stored in the anomaly determination threshold storage circuit 25 to determine whether the battery data exceeds the threshold value.

If the anomaly determination circuit 22 of the communication bridge 20 determines that the battery 35 is in the normal state and does not indicate an anomaly, the communication bridge 20 transitions to the low power consumption mode by itself (at S7 in FIG. 3, and at S112 in FIG. 4).

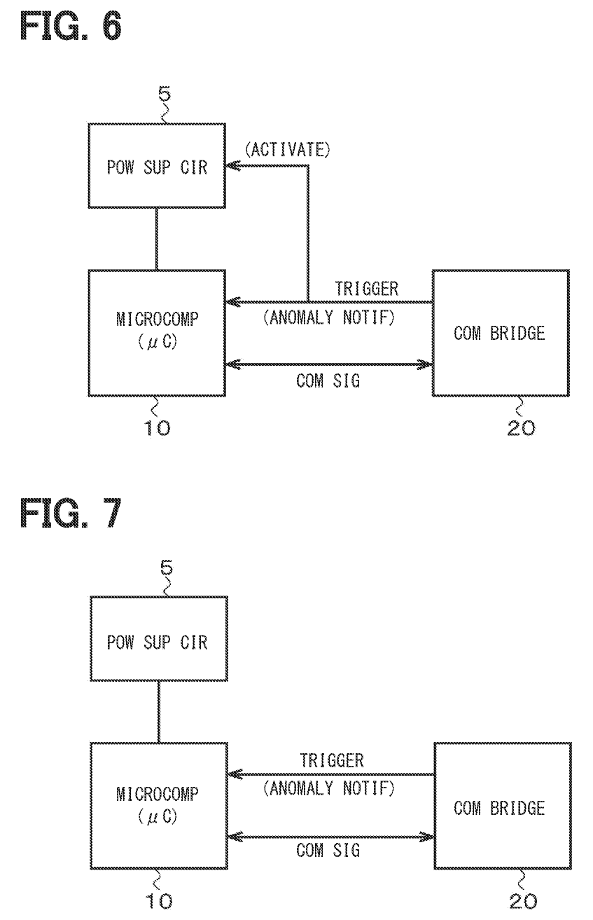

Conversely, when the anomaly determination circuit 22 of the communication bridge 20 determines that the state of the battery 35 is in the anomaly state, the communication bridge 20 activates the microcomputer 10 (at S6 in FIG. 3, and at S111a in FIG. 5). If the anomaly determination circuit 22 of the communication bridge 20 determines that the state of the battery 35 is in the anomaly state, as shown in FIG. 6, the communication bridge 20 transmits an activation signal to the power supply circuit 5 to activate the power supply circuit 5 that supplies power to the microcomputer 10. The communication bridge 20 may then start up the power supply circuit 5 to start up the microcomputer 10 . At this time, the communication bridge 20 may transmit an anomaly notification trigger to the microcomputer 10 and the power supply circuit 5 to instruct the power supply circuit 5 to start supplying power to the microcomputer 10.

As shown in FIG. 7, when the anomaly determination circuit 22 determines that the state of the battery 35 is in the anomaly state, the communication bridge 20 may notify the microcomputer 10 of an activation signal for activating the microcomputer 10, thereby activating the microcomputer 10. At this time, it may be preferable that the power supply circuit 5 continues to supply power to the microcomputer 10.

The communication bridge 20 notifies the microcomputer 10 that an anomaly has occurred in the battery 35 (at S8 in FIG. 3). When the microcomputer 10 is notified that an anomaly has occurred in the battery 35, the microcomputer 10 executes measures based on the anomaly.

At this time, after waking up from the sleep mode, the microcomputer 10 reads out the data stored in the memory device 21 and uses the date to determine the state of the battery 35 (such as SOH, and the like). Since the microcomputer 10 can acquire detailed battery data of the battery 35 from each of the monitoring circuits 41 to 43, the microcomputer 10 can determine in detail how an anomaly has occurred in the battery 35.

As shown in FIG. 9, the communication bridge 20 may write the battery data to the memory device 21, and the microcomputer 10 may read the battery data written in the memory device 21. A memory device 21 is externally connected to the communication bridge 20. Therefore, even if the communication bridge 20 transitions to a low power consumption mode after writing the battery data to the memory device 21, the microcomputer 10 can easily refer to the external memory device 21 of the communication bridge 20. This allows the microcomputer 10 to be useful in executing detailed measurements regarding the battery 35 (such as SOH measurements). The memory device 21 may be built into the communication bridge 20.

### (Summary of the present embodiment)

According to the present embodiment, the communication bridge 20 activates from the low power consumption mode autonomously separately from the microcomputer 10 and instructs the monitoring circuits 41 to 43 to acquire data related to the battery 35 (as a function of the instruction unit 20a). The communication bridge 20 acquires the battery data from the multiple monitoring circuits 41 to 43 via the communication (as a function of the acquisition unit 20b). The communication bridge 20 determines whether the state of the battery 35 is in the anomaly state or not by the anomaly determination circuit 22 based on the read battery data (as a function of the determination unit 20c).

Therefore, although the monitoring circuits 41 to 43 activate from the low power consumption mode and acquire the data, the monitoring circuits 41 to 43 does not determine whether or not there is an anomaly in the battery modules 36 to 38 in the battery 35, but only detects the anomaly. When the communication bridge 20 activates from the low power consumption mode using the power of the battery 4, the communication bridge 20 acquires the data from a plurality of monitoring circuits 41 to 43 via the communication and determines whether the state of the battery 35 is in the anomaly state. Since the communication bridge20 determines whether or not there is an anomaly based on the data acquired from a plurality of monitoring circuits 41 to 43, the anomaly can be determined without activating the microcomputer 10.

The communication bridge 20 functions as a master and the monitoring circuits 41 to 43 function as slaves. The activation time of each monitoring circuit 41 to 43 that consumes the power from the battery modules 36 to 38 can be averaged, and the variation in current consumption of the battery modules 36 to 38 can be minimized.

Furthermore, the communication bridge 20 can execute the measurements autonomously without depending on the microcomputer 10, and can wake up the microcomputer 10 only when an anomaly occurs. The communication bridge 20 can collect the battery data from all the monitoring circuits 41 to 43, and therefore can grasp the overall battery data of the battery 35. In the technique according to the conceivable technique, the battery cells as an anomaly detection target are limited to the battery cells monitored by the monitoring circuit so that the target battery cells are limited to be disposed immediately adjacent to the monitoring circuit. But in this embodiment, it is possible to detect temperature deviation anomaly and voltage deviation anomaly for the entire battery 35. Although one communication bridge 20 is sufficient per system, multiple monitoring circuits 41 to 43 are required. Therefore, in this embodiment, the number of memories per system can be reduced, which contributes to lower costs and smaller size.

### (Comparative Example)

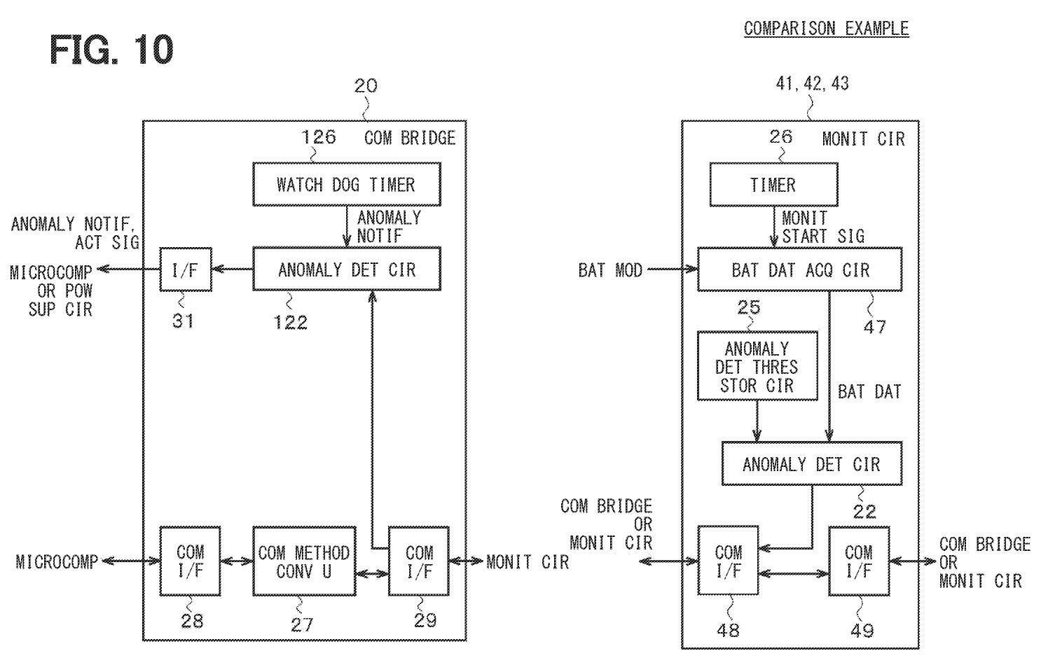

FIG. 10 shows a configuration of a comparative example. According to the configuration of this comparative example, the monitoring circuits 41 to 43 include the anomaly determination circuit 22, the anomaly determination threshold storage circuit 25, and the timer 26 described above. When the monitoring circuits 41 to 43 measure the passage of a predetermined time using the timer 26 in the low power consumption mode, the monitoring circuits 41 to 43 generate a monitor start signal so that the battery data acquisition circuit 47 acquires voltage data (as battery data) of each battery cell of the battery modules 36 to 38.

The anomaly determination circuit 22 then compares the acquired battery data with the threshold value of the anomaly determination threshold storage circuit 25 to determine the presence or absence of an anomaly. If an anomaly is detected, the plurality of monitoring circuits 41 to 43 will transmit information about the anomaly to the anomaly determination circuit 122 of the communication bridge 20 via the communication I/Fs 48 and 29. On the other hand, the communication bridge 20 is activated when an activation signal is given from the monitoring circuits 41 to 43 in the low power consumption mode. At this time, when the anomaly determination circuit 122 receives a notification of an anomaly from the monitoring circuits 41 to 43, the anomaly determination circuit 122 notifies the microcomputer 10 of the anomaly. Furthermore, the communication bridge 20 measures a specific time using the watchdog timer 126, and if no notification is received from the monitoring circuits 41 to 43 within this specific time, the communication bridge 20 determines that an anomaly has occurred in the insulation communication path 50, and notifies the microcomputer 10 of this anomaly.

According to such a configuration, for example, when the multiple monitoring circuits 41 to 43 are in a low power consumption mode, the multiple monitoring circuits 41 to 43 are activated by their respective individually provided timers 26, and if an anomaly occurs, each of the monitoring circuits will notify the communication bridge 20 of the occurrence of the anomaly at the respective timing of activation.

When the multiple monitoring circuits 41 to 43 simultaneously notify the occurrence of an anomaly, multiple anomaly signals are simultaneously present on one insulation communication path 50. In this case, an arbitration function is required to determine which anomaly signal from the monitoring circuits should have priority, so that it may not be undesirable since the communication protocol becomes complicated.

As another comparative example, if a method is adopted in which the multiple monitoring circuits 41-43 are activated in sequence through communication between them and then the state of the battery 35 is detected, a time lag is likely to occur in the timing of monitoring the states of the battery modules 36-38. Since the battery modules 36-38 are configured by connecting the battery cells in series or in series-parallel, in order for the microcomputer 10 and the like to use the voltage data of the battery cells to determine detailed SOH, and the like, it may be desirable to synchronize the monitoring timing of each battery module 36-38 as much as possible.

According to this embodiment, the communication bridge 20 first activates the multiple monitoring circuits 41 to 43, and then transmits various commands for battery monitoring and control. Thus, it is not necessary to provide a separate arbitration function. Furthermore, the time difference between the voltage monitoring timings of the battery cells constituting the battery modules 36 to 38 can be reduced.

Furthermore, in the conceivable technique, there were cases where battery data information was unavailable when the ignition switch was turned off. In such a case, the microcomputer 10 estimates the SOH based on battery data information only while the vehicle is travelling. However, the degree of deterioration of the battery 35 also varies depending on the temperature environment and battery voltage while the vehicle is stopped. Therefore, if there is information on the battery data while the vehicle is stopped, the microcomputer 10 can estimate the SOH with higher accuracy. In this embodiment, by storing information on the battery data while the ignition switch is in an off state in the memory device 21, the microcomputer 10 is able to estimate the SOH with high accuracy.

### (Second Embodiment)

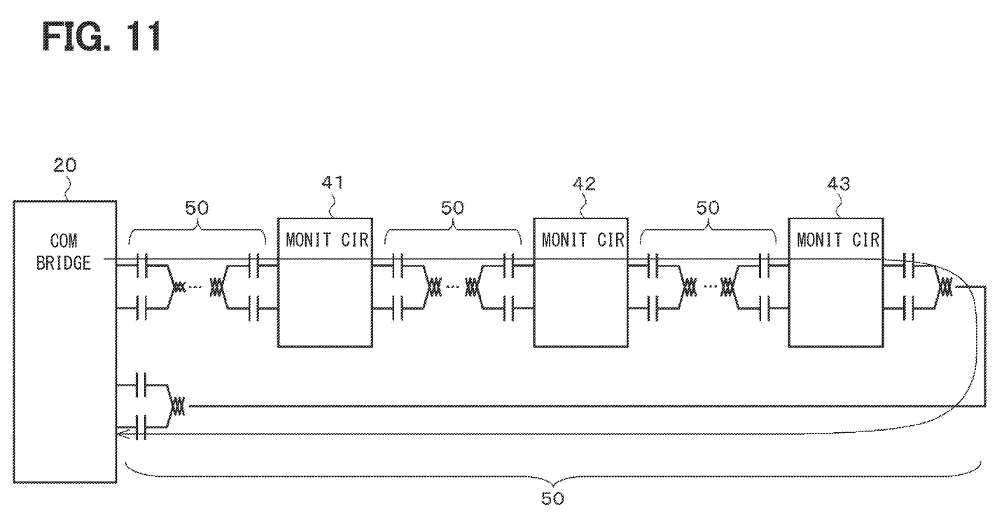

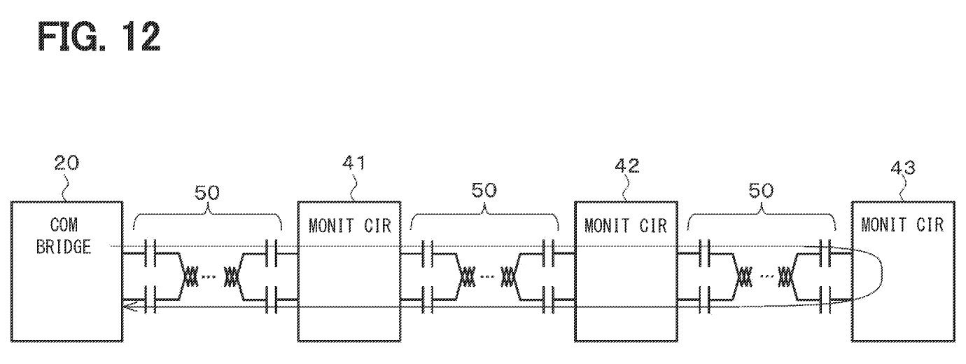

A second embodiment will be described with reference to FIGS. 11 and 12. In the above-described embodiment, the monitoring circuits 41 to 43 are described as transmitting the battery data to the communication bridge 20 upon receiving a data read command in response to the reception of the data read command. Alternatively, it may be preferable that the transmission method is executed as shown in FIG. 11 or FIG. 12.

A case where the communication bridge 20 transmits a data read command to the monitoring circuits 41 to 43 will be described. The data read command can be received by the plurality of monitoring circuits 41 to 43 in sequence via the communication I/Fs 48 and 49 described above. For example, as shown in FIG. 11, when a communication bridge 20 and multiple monitoring circuits 41 to 43 are connected in a ring shape by an insulation communication path 50, the monitoring circuits 41, 42, and 43 may pass battery data in sequence with the communication bridge 20 so that the communication bridge 20 finally receives all of the battery data.

In this case, first, the monitoring circuit 41 acquires the battery data of the corresponding battery module 36, and transmits the battery data to the monitoring circuit 42 via the insulation communication path 50. When the monitoring circuit 42 receives the battery data from the monitoring circuit 41 ,the monitoring circuit 42 acquires the battery data of the corresponding battery module 37. The monitoring circuit 42 transmits the battery data of the battery modules 36 and 37 to the monitoring circuit 43 through an insulation communication path 50.

When the monitoring circuit 43 receives the battery data from the monitoring circuit 42, the monitoring circuit 43 acquires the battery data of the battery module 38, and transmits the battery data of the battery modules 36 to 38 to the communication bridge 20 via the insulation communication path 50. This allows the communication bridge 20 to receive the battery data of all the battery modules 36 to 38.

Also, for example, as shown by the arrows in FIG. 12, when the communication bridge 20 and the multiple monitoring circuits 41 to 43 are connected in series by an insulation communication path 50 and are not connected in a ring shape, the communication may be executed in a reverse manner.

For example, when the communication bridge 20 transmits a data read command to the monitoring circuits 41 to 43, the monitoring circuit 41 acquires the battery data from the corresponding battery module 36 and transmits the battery data to the monitoring circuit 42 via the insulation communication path 50. The monitoring circuit 42 acquires the battery data of the corresponding battery module 37, and transmits the battery data of the battery modules 36 and 37 to the monitoring circuit 43 via the insulation communication path 50. The monitoring circuit 43 acquires the battery data of the corresponding battery module 38, and transmits the battery data of the battery modules 36 and 38 to the communication bridge 20 via the insulation communication path 50 and the monitoring circuits 42 and 41. This allows the communication bridge 20 to acquire the battery data of all the battery modules 36 to 38.

Alternatively, as another method, the monitoring circuit 43 acquires the battery data of the corresponding battery module 38, and transmits the battery data to the communication bridge 20 via the insulation communication path 50. The monitoring circuit 42 acquires the battery data of the corresponding battery module 37, and transmits the battery data of the battery modules 38 and 37 to the communication bridge 20 via the insulation communication path 50.

The monitoring circuit 41 acquires the battery data of the corresponding battery module 36, and transmits the battery data of the battery module 36 to the communication bridge 20 via the insulation communication path 50. This allows the communication bridge 20 to acquire the battery data of all the battery modules 36 to 38. In any one of methods, it is possible for the communication bridge 20 to acquire the battery data of all the battery modules 36 to 38 that constitute the battery 35. Therefore, the present embodiment provides similar technical effect as the foregoing embodiments.

### (Other Embodiments)

The present disclosure is not limited to the embodiment described above, and, for example, may be modified or expanded, which will be described.

The means and the method thereof of the present disclosure may be implemented by a dedicated computer provided by configuring a processor and a memory programmed to execute one or more functions embodied by a computer program. Alternatively, the means and the technique according to the present disclosure may be achieved by a dedicated computer provided by constituting a processor with one or more dedicated hardware logic circuits.

Alternatively, the control device and method described in the present disclosure may be realized by one or more dedicated computer, which is configured as a combination of a processor and a memory, which are programmed to perform one or more functions, and a processor which is configured with one or more hardware logic circuits. The computer program may also be stored on a computer-readable and non- transitory tangible storage medium as an instruction executed by a computer.

In the drawing, reference number 4 indicates a battery (i.e., power source), reference number 5 indicates a power supply circuit, reference number 10 indicates a microcomputer, reference number 20a indicates an instruction unit, reference number 20b indicates an acquisition unit, reference number 20c indicates a determination unit, reference number 21 indicates a storage device (i.e., memory device), reference number 22 indicates an anomaly determination circuit (i.e., determination unit), reference number 35 indicates a battery, reference numbers 36 to 38 indicate battery modules, reference numbers 41 to 43 indicate monitoring circuits, and reference number 50 indicates an insulation communication path (i.e., communication path).

The present embodiments include the following features in addition to the aspects of the embodiments.

Feature 1: A battery monitoring system monitors a state of a battery having a plurality of battery cells. The battery monitoring system includes: a plurality of monitoring circuits each of which is connected in series via a communication path and uses a power of a battery module to which each of the plurality of monitoring circuit is assigned to acquire data relating to the battery module; a microcomputer that monitors a state of the battery during a normal operation; and a communication bridge that is a circuit connected to at least one of the plurality of monitoring circuits via the communication path and configured to transition to a low power consumption mode that consumes less power than the normal operation when the microcomputer is in a sleep mode. The communication bridge includes: an instruction unit that activates from the low power consumption mode autonomously from the microcomputer using a power source different from the battery module and issues an instruction to acquire the data relating to the battery; an acquisition unit that acquires the data from the plurality of monitoring circuits through communication; and a determination unit that determines whether the state of the battery is in an anomaly state based on acquired data.

Feature 2: In the battery monitoring system according to feature 1, when the microcomputer is in the sleep state, the plurality of monitoring circuits have been transitioned to the low power consumption mode, and the communication bridge activates the plurality of monitoring circuits in the low power consumption mode through the communication path.

Feature 3: In the battery monitoring system according to feature 1 or 2, the communication bridge notifies the microcomputer of an activation signal for activating the microcomputer when the determination unit determines that the state of the battery is in the anomaly state.

Feature 4: In the battery monitoring system according to feature 1, when the determination circuit determines that the state of the battery is in the anomaly state, the communication bridge transmits an activation signal for activating a power supply circuit to the power supply circuit that supplies a power to the microcomputer, and the microcomputer is activated by activating the power supply circuit.

Feature 5: In the battery monitoring system according to any one of features 1 to 4, the communication bridge transitions to the low power consumption mode by itself when the determination unit determines that the state of the battery is in an normal state.

Feature 6: In the battery monitoring system according to any one of features 1 to 5, the communication bridge stores the acquired data in a memory (21).

Feature 7: In the battery monitoring system according to feature 6, the microcomputer reads data stored in the memory after the microcomputer wakes up from the sleep mode and determines the state of the battery using the data.

Although the present disclosure has been described in accordance with the embodiments, it is understood that the present disclosure is not limited such embodiments or structures described in the embodiments. The present disclosure includes various modifications or deformations within an equivalent range. In addition, while the various combinations and configurations, which are preferred, other combinations and configurations, including more, less or only a single element, are also within the spirit and scope of the present disclosure.

It is noted that a flowchart or the processing of the flowchart in the present application includes sections (also referred to as steps), each of which is represented, for instance, as S1. Further, each section can be divided into several sub-sections while several sections can be combined into a single section. Furthermore, each of thus configured sections can be also referred to as a device, module, or means.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A battery monitoring system that monitors a state of a battery having a plurality of battery cells, the battery monitoring system comprising:
a plurality of monitoring circuits each of which is connected in series via a communication path and uses a power of a battery module to which each of the plurality of monitoring circuit is assigned to acquire data relating to the battery module;
a microcomputer that monitors a state of the battery during a normal operation; and
a communication bridge that is a circuit connected to at least one of the plurality of monitoring circuits via the communication path and configured to transition to a low power consumption mode that consumes less power than the normal operation when the microcomputer is in a sleep mode, wherein: the communication bridge includes:
an instruction unit that activates from the low power consumption mode autonomously from the microcomputer using a power source different from the battery module and issues an instruction to acquire the data relating to the battery module;
an acquisition unit that acquires the data relating to the battery module from the plurality of monitoring circuits through communication; and
a determination unit that determines whether the state of the battery is in an anomaly state based on acquired data.

2. The battery monitoring system according to claim 1, wherein:
when the microcomputer is in the sleep mode, the plurality of monitoring circuits have been transitioned to the low power consumption mode; and
the communication bridge activates the plurality of monitoring circuits from the low power consumption mode through the communication path.

3. The battery monitoring system according to claim 1, wherein:
the communication bridge notifies the microcomputer of an activation signal for activating the microcomputer when the determination unit determines that the state of the battery is in the anomaly state.

4. The battery monitoring system according to claim 1, wherein:
when the determination unit determines that the state of the battery is in the anomaly state, the communication bridge transmits an activation signal for activating a power supply circuit to the power supply circuit that supplies a power to the microcomputer; and the microcomputer is activated by activating the power supply circuit.

5. The battery monitoring system according to claim 1, wherein:
the communication bridge transitions to the low power consumption mode by itself when the determination unit determines that the state of the battery is in an normal state.

6. The battery monitoring system according to claim 1, wherein:
the communication bridge stores the acquired data in a memory.

7. The battery monitoring system according to claim 6, wherein:
the microcomputer reads data stored in the memory after the microcomputer wakes up from the sleep mode and determines the state of the battery using the data.

8. The battery monitoring system according to claim 1, wherein:
the communication bridge and the plurality of monitoring circuits are connected in a daisy chain;
the communication path is configured to be an insulation path using a plurality 2/6 of capacitors or a plurality of transformers as insulation elements; and
the communication between the communication bridge and the plurality of monitoring circuits are executed in an insulation manner.

9. The battery monitoring system according to claim 1, wherein:
each of the plurality of monitoring circuits has a function for detecting a voltage of each battery cell in the battery module, an equalization function for equalizing the voltage of each battery cell in the battery module, and a function for detecting temperature of the battery module; and
the data relating to the battery module indicates voltage data of each battery cell, position information of each battery cell, identification information of each monitoring circuit, information for determining a chronological time of acquisition of the data, and detection data of gas released from the battery.

10. The battery monitoring system according to claim 1, wherein:
the communication path is configured to be an insulation path using a plurality of capacitors or a plurality of transformers as insulation elements; and
each of the plurality of monitoring circuits transmits the data relating to the battery module to the communication bridge when each of the plurality of monitoring circuits receives the instruction to acquire the data relating to the battery module from the instruction unit.

11. The battery monitoring system according to claim 1, wherein:
the communication path is configured to be an insulation path using a plurality of capacitors or a plurality of transformers as insulation elements;
each of the plurality of monitoring circuits further includes a communication I/F;
each of the plurality of monitoring circuits receives the instruction to acquire the data relating to the battery module from the instruction unit in sequence via the 3/6 communication I/F;
the communication bridge and the plurality of monitoring circuits are connected in a ring shape by the communication path; and
each of the plurality of monitoring circuits passes the data relating to the battery module in sequence with the communication bridge so that the communication bridge finally receives the data relating to the battery module from all of the plurality of monitoring circuits.

12. The battery monitoring system according to claim 1, wherein:
the communication path is configured to be an insulation path using a plurality of capacitors or a plurality of transformers as insulation elements;
the communication bridge and the plurality of monitoring circuits are connected in series by the communication path;
the communication between the communication bridge and the plurality of monitoring circuits are executed in a reverse manner;
when the communication bridge transmits the instruction to acquire the data relating to the battery module from the instruction unit to the monitoring circuits, one of the plurality of monitoring circuits acquires the data relating to the battery module and transmits the data relating to the battery module to an adjacent one of the plurality of monitoring circuits via the communication path;
the adjacent one of the plurality of monitoring circuits acquires the data relating to a corresponding battery module and transmits the data relating to the battery module and the corresponding battery module to adjacent another one of the plurality of monitoring circuits via the communication path; and
the communication bridge finally receives the data relating to the battery module from all of the plurality of monitoring circuits.

13. The battery monitoring system according to claim 1, wherein:
each of the plurality of monitoring circuits activates from the low power consumption mode and acquires the data relating to the battery module without determining whether the state of the battery is in the anomaly state;
the communication bridge determines whether the state of the battery is in the anomaly state based on the acquired data without activating the microcomputer;
an activation time of each of the plurality of monitoring circuits that consumes the power of the battery module is averaged; and
a variation in current consumption of the battery module is minimized.

14. The battery monitoring system according to claim 1, wherein:
the battery is configured by connecting a plurality of battery modules in series or in series parallel;
the power source different from the battery module is an auxiliary battery;
the microcomputer operates by receiving power supply from the power source through a power supply circuit; and
when the microcomputer is transitioned to the sleep mode, an operation of the power supply circuit that supplies the power supply to the microcomputer is shut down, or the microcomputer is directly instructed to transition into the sleep mode so that a power consumption of the microcomputer is suppressed and achieve a low power consumption.

15. The battery monitoring system according to claim 1, wherein:
the communication bridge further includes a timer and a monitoring circuit control unit;
the timer counts time when the communication bridge transitions to the low power consumption mode;
the timer outputs a monitor start signal to the monitoring circuit control unit after 5/6 a predetermined time has elapsed;
when the monitoring circuit control unit receives the monitor start signal from the timer, the monitoring circuit control unit outputs an activation signal to the monitoring circuits via a communication I/F, and outputs an instruction signal for instructing to acquire the data; and
in the low power consumption mode, the communication bridge executes counting by the timer and autonomously activates when the predetermined time has elapsed according to a normal operation.
